(19) United States
(12) Patent Application Publication
(10) Pub. No.: US 2005/0282314 A1
(43) Pub. Date: Dec. 22, 2005

(54) Printed circuit boards and methods for fabricating the same

(75) Inventors: Kuang-Lin Lo, Kaohsiung County (TW); Jen-Kuang Fang, Pingtung County (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/150,346

(22) Filed: Jun. 13, 2005

(30) Foreign Application Priority Data
Jun. 17, 2004 (TW) 93117470

(51) Int. Cl. H01L 21/44

(52) U.S. Cl. 438/117

(57) ABSTRACT

Printed circuit boards and methods for fabricating the same. A via in a printed circuit board electrically connects to trace lines of the PCB, such that only one plating line is required to electrically connect a plating bus and the plating through hole. Thus, in an electroplating step, current can flow to fingers in the trace lines to plate an anti-oxidation metal layer thereon. The via is separated into several sub-vias to electrically isolate the plating line from trace lines and fingers, each of which connects to the plating line or the trace lines. Finally, at least one plating line remains, thus avoiding negative impact on electrical performance of an electronic device that uses the printed circuit board.

### BACKGROUND

The invention relates to a fabrication method for a printed circuit board (PCB), and more particularly to a method of plating a metal layer of the PCB.

PCBs, such as substrates for ball grid array (BGA) packages, generally have exposed pads or fingers for connection to an external device.

In FIG. 1, a top view of an exemplary portion of a PCB for a BGA substrate is shown. Fingers 140 are disposed in a chip attachment area 120. Trace lines 150 on a top surface respectively extend from fingers 140 to vias 160 and electrically connect to pads 130 on a bottom surface using trace lines on the bottom surface. A bus line 180, disposed at an edge of the PCB, electrically connects to trace lines 150, fingers 140, and pads 130 using branch plating lines 181. The pads 130, fingers 140, trace lines 150, bus line 180, and branch plating lines 181 are typically copper. The pads 130 and fingers 140 are typically exposed for electrical connection to external devices (not shown). The pads 130 and fingers 140 are usually plated with a Ni/Au layer (not shown) by electrical plating such that current flows to every pad 130 and finger 140 using bus line 180 and branch plating lines 181 to protect the exposed pads 130 and fingers 140 from oxidation.

The connections between respective trace lines 150 and bus lines 180 are cut step to separate an encapsulated package from the PCB. The branch lines 181, however, remain in the package.

Due to the demand for small-aspect, light and powerful electronic products, PCB design rules demand layouts with increased density, resulting in increased overall density and reduced pitch in the remaining branch lines 181, and increased distribution density of the vias 160. The vias 160 suffer from the increased wiring density as follows:

Via size decreases with increased wiring density, resulting in difficulty drilling, electroplating through holes to form the vias, with increased aspect ratio of the through holes negatively affecting the product reliability, and decreased durability of the vias.

Moreover, crosstalk resulting from mutual inductance and capacitors between the branch lines 181 may not only negatively affect transmission of electrical signals and system stability, but also deviate character impedances of trace lines 150, thereby further negatively affecting the electrical performance of an end product using the PCB.

### SUMMARY

Thus, embodiments of the invention provide PCBs and methods for fabricating the same, capable of reducing density of remaining plating lines to improve electrical performance of end products using the PCB, maintaining via size when increasing wiring density of the PCB to simplify drilling and electroplating for via formation and improve via reliability, and electrically isolating the plating line from the trace line and pads when completing electroplating to prevent the plating line negatively affecting electrical performance of other parts of the wiring.

Embodiments of the invention provide a fabrication method for PCBs. First, a substrate, comprising a layout area and a periphery area on a surface, is provided. A patterned wiring layer, comprising a bus line in the periphery area, a via in the layout area, at least one pad in the layout area, a plating line electrically connecting the bus line and the via, and a trace line electrically connecting the via and the pad, is then formed overlying the substrate. A metal layer is further formed overlying the pad. Finally, the via is separated into a plurality of sub-vias electrically isolated from each other. The sub-vias connect to at least the plating line or the trace line.

Embodiments of the invention further provide a printed circuit board (PCB). The PCB comprises a substrate and a patterned wiring layer. The substrate comprises a layout area and a periphery on a surface. The patterned wiring layer overlies the substrate. The wiring layer further comprises a bus line, at least one pad, a separated via, a plating line and at least one trace line. The bus line is disposed in the periphery area. The at least one pad comprises a metal layer thereon and is disposed in the layout area. The separated via comprises a plurality of sub-vias electrically isolated from each other and is disposed in the layout area. The plating line electrically connects the bus line and the via. The at least one trace line electrically connects the sub-vias and the at least one pad.

### BRIEF DESCRIPTION OF THE DRAWINGS

Embodiments of the invention can be more fully understood by reading the subsequent detailed description in conjunction with the examples and references made to the accompanying drawings, wherein:

FIG. 1 is a top view of a conventional PCB.

FIGS. 2A, 2B, and 2D through 2I are top views of fabrication methods of PCBs of exemplary embodiments of the invention.

FIG. 2C is a cross-section of a via of PCBs of exemplary embodiments of the invention.

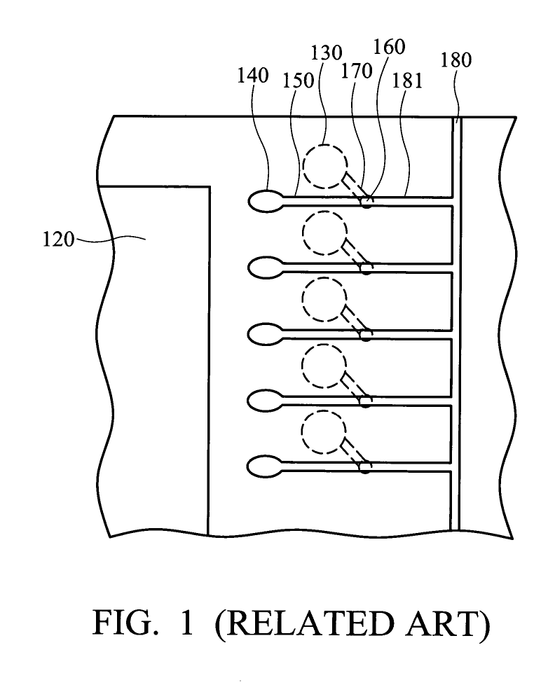

### DETAILED DESCRIPTION

The following embodiments are intended to illustrate the invention more fully without limiting the scope of the claims, since numerous modifications and variations will be apparent to those skilled in this art.

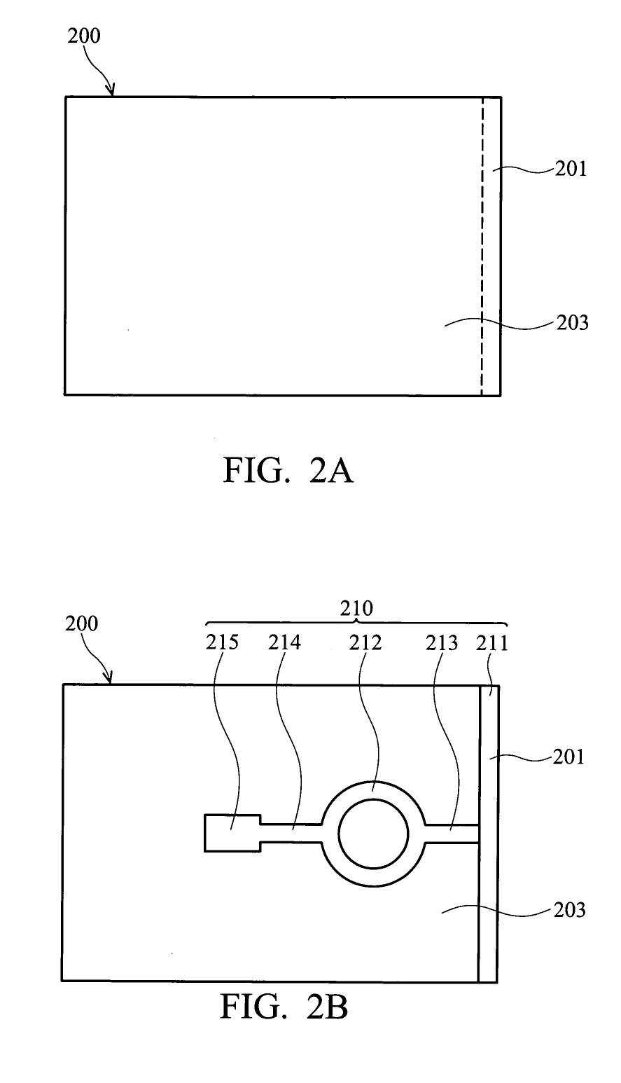

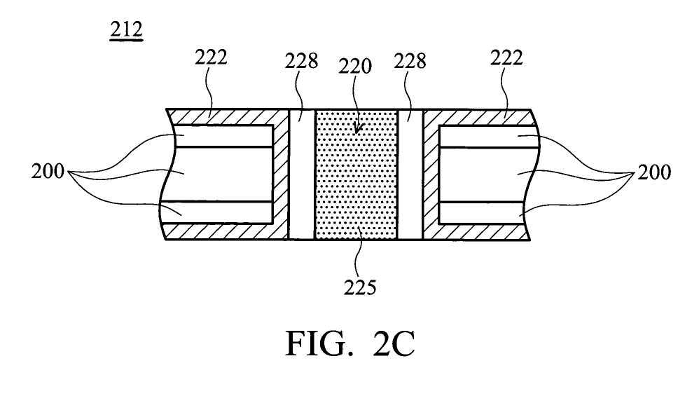

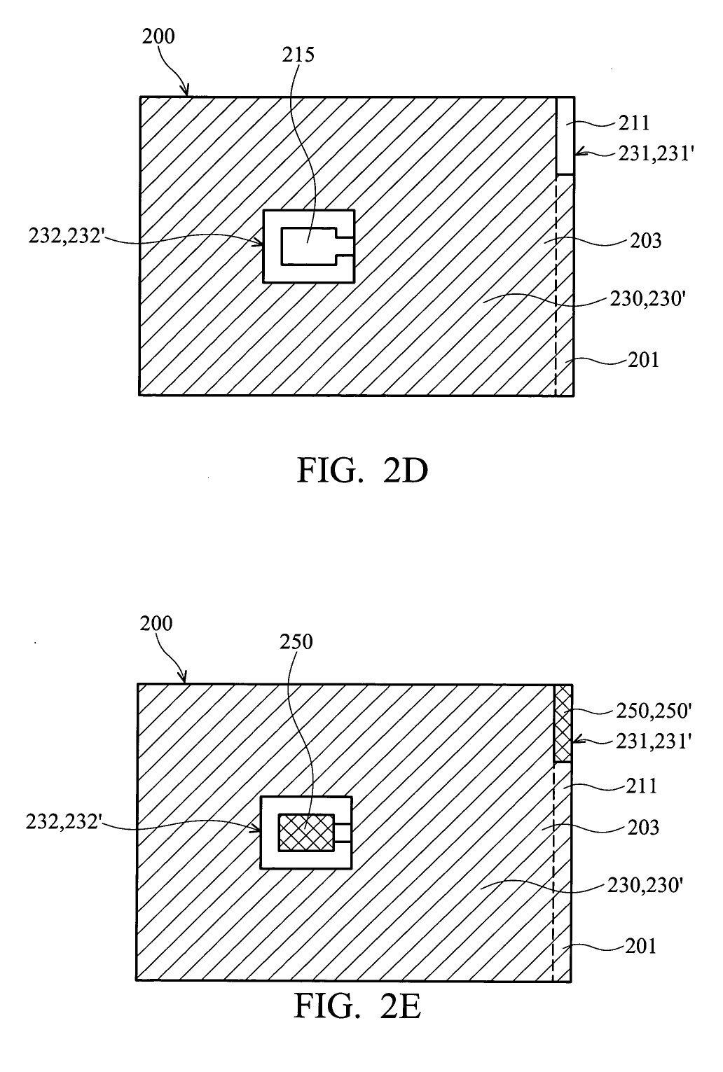

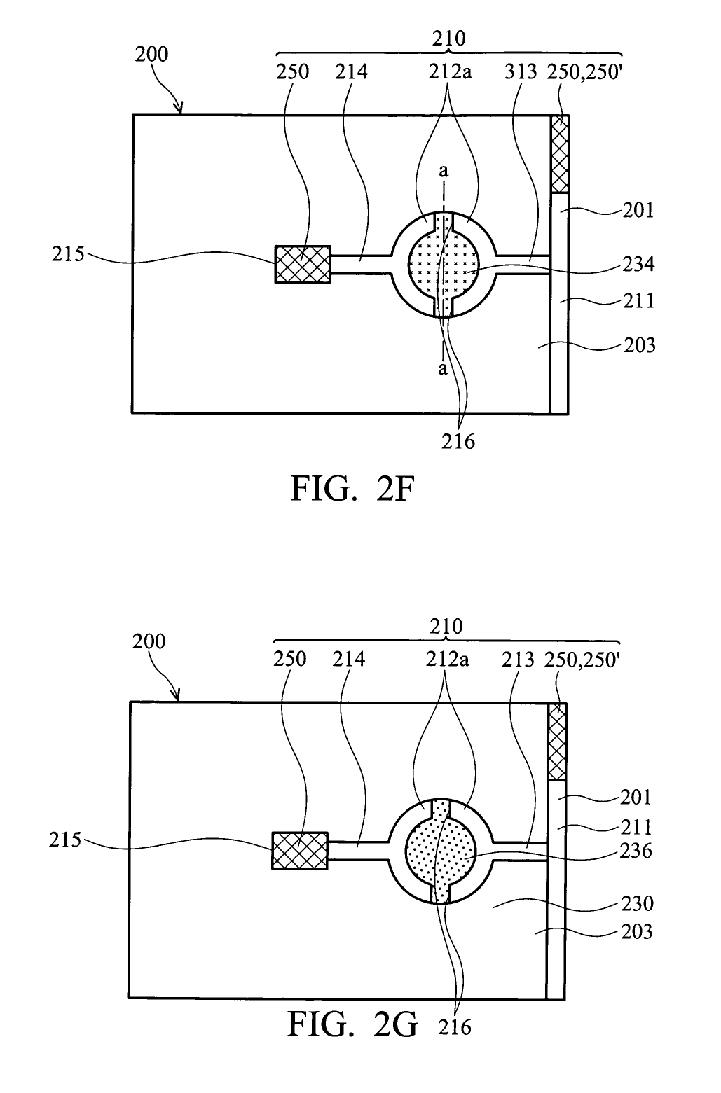

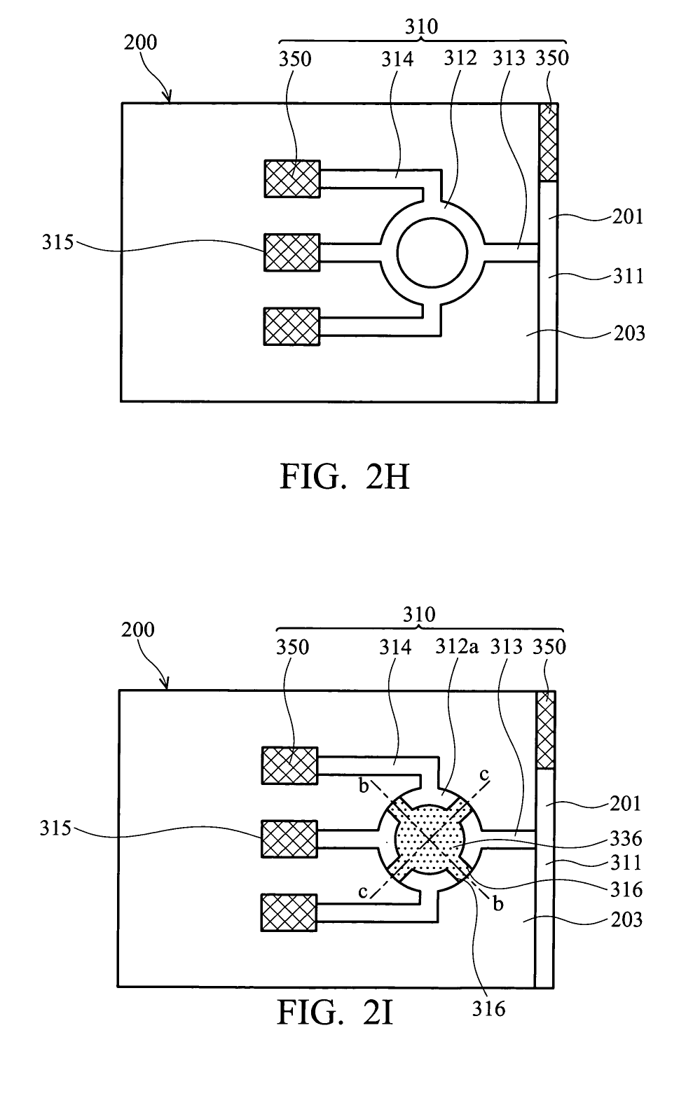

FIGS. 2A through 2I show exemplary embodiments of PCBs of the invention and methods for fabricating the same.

As shown in FIG. 2A, a substrate 200, such as a core substrate comprising fiber-reinforced or particle-reinforced materials such as epoxy resin, bismaleimide triazine-based (BT), Cyanate ester, or other materials, is provided. The substrate 200 may also be a core substrate plated with patterned wiring with an overlying dielectric layer. One surface of substrate 200, such as that for connection to an external device, has a periphery 201 and layout area 202.

FIGS. 2B through 2I illustrate an exemplary portion of the PCB of the invention. In practice, the quantity, shape, and size of the elements shown in the figures may be modified.

In FIG. 2B, a wiring layer 210 is formed overlying the surface of substrate 200. A metal layer formed overlying substrate 200, followed by patterning of the metal layer, forms wiring layer 210. The metal layer is copper, tin, nickel, chrome, titanium, copper-chrome alloy, or tin-lead alloy. Alternatively, the wiring layer can be formed by physical vapor deposition such as sputtering or metal-organic chemical vapor deposition (MOCVD) directly in a predetermined pattern. In wiring layer 210, a bus line 211 is disposed in the periphery 201 (shown in FIG. 2A) of substrate 200, a via 212 is disposed in the layout area 203, a conductive finger 215 is disposed in the layout area 203, a plating line 213 electrically connects the bus line 211 and the via 212, and a trace line 214 electrically connects the via 212 and the conductive finger 215.

An exemplary via 212 is shown in FIG. 2C. Formation of via 212 includes a through hole 220 formed in the substrate 200 by a method such as laser drilling or mechanical drilling, followed by conformal formation of a copper seed layer 222 overlying the substrate 200 and the through hole 220 utilizing electroless plating. A mask layer such as a resist layer or dry film, comprising an opening exposing the seed layer 222 on sidewalls of the through hole 222, is formed overlying the substrate 200 by a method such as stencil printing, spin coating, or laminating. Next, a copper layer 228 is formed overlying the seed layer 222 by electroplating, providing electrical connection of the subsequently formed wiring layer and the underlying circuitry, followed by removal of the mask layer. Finally, the via 212 is filled with a dielectric plug 230. Subsequently, the metal layer 228 overlying the substrate 200 is patterned to form a wiring layer.

In FIG. 2B, an anti-oxidation layer is formed overlying the conductive finger 215 by electroplating utilizing current through electrical connection of the plating line 213, via 212, and trace line 214. Two exemplary methods for forming the anti-oxidation layer follow.

### EXAMPLE 1 OF FORMATION OF THE ANTI-OXIDATION LAYER

FIGS. 2D through 2G show exemplary methods for forming the anti-oxidation layer for PCBs, following that shown in FIG. 2B. In FIG. 2D, a patterned solder mask 230 is formed overlying the substrate 200 (shown in FIG. 2A). The solder mask 230 comprises an opening 231 exposing the bus line 211 and an opening 232 exposing the conductive finger 215. The openings 231 and 232 are formed by a method such as photolithography or laser drilling.

In FIG. 2E, the substrate 200 is immersed in an electro-bath, followed by supply of current to exposed conductive finger 215 from bus line 211 via plating line 213 and via 212 sequentially. Thus, an anti-oxidation layer 250, of gold, nickel, palladium, silver, tin, nickel/palladium, chrome/titanium, nickel/gold, palladium/gold, or nickel/palladium/gold, is plated overlying the bus line 211 exposed by the opening 231 and the conductive finger 215 exposed by the opening 232.

In FIG. 2F, the solder mask 230 is shown transparently, revealing the underlying wiring layer 210. A mechanical drill or laser drill at the solder mask side cuts the via 212 along line a-a to separate the via 212 into two electrically isolated sub-vias 212a and form two isolation trenches 216 on the via 212, exposing parts of sidewalls of the through hole and a bottom layer 234. One sub-via 212a connects to the plating line 213, and the other connects to the trace line 214.

In FIG. 2G, the solder mask 230 is shown transparently, revealing the underlying wiring layer 210. The isolation trenches 216 and via 212 are filled with an insulating material 236.

### EXAMPLE 2 FOR FORMATION OF THE ANTI-OXIDATION LAYER

FIGS. 2D through 2G show another exemplary methods for forming the anti-oxidation layer for PCBs, following that shown in FIG. 2B. In FIG. 2D, a patterned resist layer 230′ is formed overlying the substrate 200 (shown in FIG. 2A). The resist layer 230′ comprises an opening 231′ exposing the bus line 211 and an opening 232′ exposing the conductive finger 215. The openings 231 and 232 are formed by a method such as photolithography or laser drilling.

In FIG. 2E, the substrate 200 is immersed in an electro-bath, followed by supply of current to exposed conductive finger 215 from bus line 211 via plating line 213 and via 212 sequentially. Thus, an anti-oxidation layer 250, of gold, nickel, palladium, silver, tin, nickel/palladium, chrome/titanium, nickel/gold, palladium/gold, or nickel/palladium/gold, is plated overlying the bus line 211 exposed by the opening 231′ and the conductive finger 215 exposed by the opening 232′.

In FIG. 2F, the patterned resist layer 230′ is removed by a method such as etching, exposing the underlying wiring layer 210. A mechanical drill or laser drill at the solder mask side cuts the via 212 along line a-a to separate the via 212 into two electrically isolated sub-vias 212a and form two isolation trenches 216 on the via 212, exposing parts of sidewalls of the through hole and a bottom layer 234. One sub-via 212a connects to the plating line 213, and the other connects to the trace line 214.

In FIG. 2G, the solder mask 230 is shown transparently, revealing the underlying wiring layer 210. The isolation trenches 216 and via 212 are filled with an insulating material 236, followed by forming a solder mask (not shown) overlying the substrate 200, exposing the conductive finger 215.

FIGS. 2H and 2I show an alternative embodiment, following that shown in FIG. 2A, of PCBs of the invention and methods for fabricating the same.

In FIG. 2H, a wiring layer 310 is formed overlying the surface of substrate 200, comprising a metal layer formed overlying substrate 200, followed by patterning of the metal layer. The metal layer is copper, tin, nickel, chrome, titanium, copper-chrome alloy, or tin-lead alloy. Alternatively, the wiring layer 310 can be formed by physical vapor deposition such as sputtering or metal-organic chemical vapor deposition (MOCVD) directly in a predetermined pattern. In wiring 310, a bus line 311 is disposed in the periphery area 201 (shown in FIG. 2A) of substrate 200, a via 312 is disposed in the layout area 203, three conductive fingers 315 are disposed in the layout area 203, a plating line 313 electrically connects the bus line 311 and the via 312, and three trace lines 314 electrically connect the via 212 and the respective conductive fingers 315.

Formation of the via 312 is substantially the same as the description in FIG. 2C, and thus, is omitted herefrom. Further, an anti-oxidation layer 350 is formed respectively overlying the conductive fingers by electroplating utilizing electrical connection of the plating line 313, via 312, and trace lines 314. Exemplary methods for forming the anti-oxidation layer 350 are substantially the same as the descriptions for FIGS. 2D through 2G, and thus, are omitted herefrom.

FIG. 2I shows separation of the via 312 of this embodiment. A mechanical drill or laser drill cuts the via 312 along lines b-b and c-c to separate the via 312 into four electrically isolated sub-vias 312a and form four isolation trenches 316 on the via 312, exposing parts of sidewalls of the through hole and a bottom layer 334. One sub-via 312a connects to the plating line 313, and the others respectively connect to the trace lines 314, followed by filling an insulating material 336 in the trenches 316 and the via 312.

As described, the invention discloses the via 212 electrically connecting to the trace line 214 and the via 312 electrically connecting to the trace lines 314. Thus, at least one plating line 213 is required to connect the via 212 and bus line 211, and at least one plating line 313 is required to connect the via 312 and bus line 311. Current may flow to finger 250 in the trace line 214 via the plating line 213 and the via 212, and to fingers 350 in the corresponding trace lines 314 via the plating line 313 and the via 312 to respectively electroplate the anti-oxidation layers 250 and 350 overlying the conductive fingers 215 and 315. Finally, only one plating line 213/313 remains, which does not negatively affect the electrical performance of end products utilizing the PCBs of the invention.

Further, the invention discloses the via 212 separated into two sub-vias 212a and the via 312 separated into four sub-vias 312a to replace the reduced via of the known art, increasing the wiring density of the PCBs, and electrically isolating the plating line 213 from the trace line 214 and the pad 215, and the plating line 313 from the trace lines 314 and the pads 315. The separation of the vias 212 and 312 simplifies the drilling and electroplating of the vias 212 and 312, improving via reliability and simplifying the electrical isolation process for the plating line.

As shown in FIG. 2I, the PCB of an exemplary embodiment of the invention comprises a substrate 200 and a patterned wiring layer 310 overlying a surface of the substrate 200. The substrate 200 comprises a layout area 203 and a periphery 201 on the surface. The wiring layer 310 is copper, tin, nickel, chrome, titanium, copper-chrome alloys, or tin-lead alloys.

The wiring layer 310 further comprises a bus line 311, a plurality of conductive fingers 315, a separated via 312, a plating line 313 and at least one trace line 314. The bus line 311 is disposed in the periphery area 203. The conductive fingers 315 respectively comprise an anti-oxidation layer 350 thereon and are disposed in the layout area 203. The anti-oxidation layer 350 is gold, nickel, palladium, silver, tin, nickel/palladium, chrome/titanium, nickel/gold, palladium/gold, or nickel/palladium/gold. The separated via 312 comprises a plurality of electrically isolated sub-vias 312a and is disposed in the layout area 203. The plating line 313 connects the bus line 311 and the sub-vias 312a. One sub-via 312a connects to the plating line 313, and the others respectively connect to different trace lines 314. The at least one trace line 314 electrically connects the sub-vias 312a and the conductive fingers 315.

The via 312 comprises isolation trenches 316 on either side of the sub-vias 312a. The sub-vias 312a connect to at least the plating line 313 or the at least one trace line 314. The plating line 313 preferably connects the bus line 311 and one of the sub-vias 312a. Further, the sub-vias 312a and the isolation trenches 316 are filled with an isolating material 336.

Thus, the invention discloses separation of the via into a plurality of sub-vias to replace the reduced via of the known art, increasing the wiring density of the PCBs and simplifying the drilling and electroplating of the vias to improve via reliability. Moreover, only one plating line remains, with no negative affect on the electrical performance of end products utilizing the PCBs of the invention. The invention improves via reliability with increased wiring density and electrical performance.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

1. A fabrication method for printed circuit boards (PCBs), comprising:
providing a substrate comprising a layout area and a periphery;
forming a patterned wiring layer, comprising a bus line in the periphery, a via in the layout area, at least one pad in the layout area, a plating line electrically connecting the bus line and the via, and a trace line electrically connecting the via and the pad, overlying the substrate;
forming a metal layer overlying the pad; and
separating the via into a plurality of electrically isolated sub-vias, the sub-vias connecting to at least one of the plating line and the trace line.

2. The method as claimed in claim 1, wherein the via is separated by formation of a plurality of isolation trenches thereon.

3. The method as claimed in claim 2, wherein the isolation trenches are formed by mechanical drilling or laser drilling.

4. The method as claimed in claim 2, further comprising filling an isolating material in the sub-vias and the isolation trenches when the via is separated.

5. The method as claimed in claim 1, wherein formation of the metal layer further comprises:
forming a patterned solder mask overlying the wiring layer, the solder mask comprising a first opening exposing parts of the bus line and a second opening exposing the pad; and
electroplating the metal layer overlying the pad.

6. The method as claimed in claim 5, wherein the via is seperated after the solder mask is formed on the wiring layer.

7. The method as claimed in claim 1, wherein formation of the metal layer further comprises:
forming a patterned resist layer overlying the wiring layer, comprising a first opening exposing parts of the bus line and a second opening exposing the pad;
electroplating the metal layer overlying the pad; and
removing the resist layer.

8. The method as claimed in claim 7, further comprising forming a plurality of isolation trenches separating the via into a plurality of sub-vias on the via when the resist is removed.

9. The method as claimed in claim 8, wherein the isolation trenches are formed by mechanical drilling or laser drilling.

10. The method as claimed in claim 8, further comprising filling an isolating material in the sub-vias and the isolation trenches when the via is separated.

11. The method as claimed in claim 10, further comprising forming a solder mask overlying the wiring layer, exposing the pad when the sub-vias and the isolation trenches are filled.

12. The method as claimed in claim 1, wherein the wiring layer is copper, tin, nickel, chrome, titanium, copper-chrome alloys, or tin-lead alloys.

13. The method as claimed in claim 1, wherein the pad is a conductive finger.

14. The method as claimed in claim 1, further comprising connecting one sub-via to the plating line and respectively connecting the other sub-vias to different trace lines.

15. The method as claimed in claim 1, wherein formation of the via comprises:
forming a through hole in the substrate;
conformally forming a seed layer overlying the substrate and the through hole; and
forming a conductive layer overlying the seed layer overlying sidewalls of the through hole to electrically connect to the wiring layer of the substrate.

16. The method as claimed in claim 1, wherein the metal layer is an anti-oxidation layer of gold, nickel, palladium, silver, tin, nickel/palladium, chrome/titanium, nickel/gold, palladium/gold, or nickel/palladium/gold.
